(19) United States
(12) Patent Application Publication
(10) Pub. No.: US 2026/0094783 A1
(43) Pub. Date: Apr. 2, 2026

(54) MULTIPLE PARTICLE BEAM SYSTEM, IN PARTICULAR MULTI-BEAM PARTICLE MICROSCOPE, HAVING A FAST MAGNETIC LENS AND THE USE THEREOF

(71) Applicant: Carl Zeiss MultiSEM GmbH, Oberkochen (DE)

(72) Inventors: Stefan SCHUBERT, Oberkochen (DE); Joerg KUBISCH, Aalen (DE); Alexander BOROVIK, Heidenheim (DE); Maxim MIKIRTYCHIYANTS, Heidenheim (DE); Roland STANIA, Heidenheim (DE); Ralf BURR, Dischingen (DE); Jonas BADER, Heidenheim (DE); Thomas DIETERLE, Murrhardt (DE); Uwe NIEDERMAYER, Aalen (DE)

(21) Appl. No.: 19/412,096

(22) Filed: Dec. 8, 2025

Related U.S. Application Data
(63) Continuation of application No. PCT/EP2024/025186, filed on Jun. 13, 2024.

(30) Foreign Application Priority Data
Jun. 23, 2023 (DE) 10 2023 116 627.1

(51) Int. Cl. H01J 37/14; H01J 37/26

(52) U.S. Cl. CPC H01J 37/14; H01J 37/265; H01J 2237/002; H01J 2237/0264; H01J 2237/141

(57) ABSTRACT

A multiple particle beam system comprises: a magnetic lens through which a plurality of individual charged particle beams pass; and a controller configured to control, such as dynamically control, the magnetic lens. The magnetic lens comprises a coil, a winding body and a pole shoe. The coil is arranged around the winding body and the winding body is a hollow body through which the plurality of individual particle beams pass. The coil, together with the winding body, is arranged within the pole shoe. The pole shoe has an opening through which a magnetic field created by the magnetic lens emerges from the pole shoe and interacts with the plurality of individual particle beams to obtain a lens effect. The winding body is electrically conductive and has an interruption, by which the electrical conductivity of the winding body is interrupted in the circumferential direction around the particle-optical axis.

### CROSS-REFERENCE TO RELATED APPLICATIONS

The present application is a continuation of, and claims benefit under 35 USC 120 to, international application No. PCT/EP2024/025186, filed Jun. 13, 2024, which claims benefit under 35 USC 119 of German Application No. 10 2023 116 627.1, filed Jun. 23, 2023. The entire disclosure of each of these applications is incorporated by reference herein.

### FIELD

The disclosure relates to multiple particle beam systems which operate with a plurality of individual charged particle beams. For example, the disclosure relates to a multiple particle beam system, such as a multi-beam particle microscope, having a fast magnetic lens and the use thereof.

### BACKGROUND

With the ongoing development of ever smaller and ever more complex microstructures such as semiconductor components, there is a general desire to further develop and optimize planar production techniques and inspection systems for producing and inspecting small dimensions of the microstructures. For instance, the development and production of the semiconductor components typically involve monitoring of the design of test wafers, and the planar production techniques can involve process optimization for reliable production with high throughput. Moreover, there have been recent demands for an analysis of semiconductor wafers for reverse engineering and for a customized, individual configuration of semiconductor components. Therefore, there is a general for an inspection mechanism which can be used with high throughput to examine the microstructures on wafers with high accuracy.

Typical silicon wafers used in the production of semiconductor components have diameters of up to 300 mm. Each wafer is typically divided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case usually extends from a few μm to the critical dimensions (CD) of 5 nm, with the structure sizes becoming even smaller in the near future. In the future, structure sizes or critical dimensions (CD) are expected to be less than 3 nm, for example 2 nm, or even under 1 nm. In the case of the aforementioned small structure sizes, defects in the size of the critical dimensions are to be identified relatively quickly in a relatively large area. For several applications, the desired accuracy of a measurement provided by inspection equipment is even higher, for example by a factor of two or one order of magnitude. For instance, a width of a semiconductor feature is to be measured with an accuracy of below 1 nm, for example 0.3 nm or even less, and a relative position of semiconductor structures is to be determined with an overlay accuracy of below 1 nm, for example 0.3 nm or even less.

The MSEM, a multi-beam scanning electron microscope, is a relatively new development in the field of charged particle systems (charged particle microscopes, CPMs). For instance, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or raster. For instance, 4 to 10,000 individual electron beams can be provided as primary radiation, with each individual electron beam being separated from an adjacent individual electron beam by a pitch of 1 to 200 micrometres. For example, an MSEM has approximately 100 separate individual electron beams (“beamlets”), which are for instance arranged in a hexagonal raster, with the individual electron beams being separated by a pitch of approximately 10 μm. The plurality of individual charged particle beams (primary beams) are focused on a surface of a sample to be examined by way of a common objective lens. For example, the sample can be a semiconductor wafer which is secured to a wafer holder mounted on a movable stage. When the wafer surface is illuminated by the individual primary charged particle beams, interaction products, for example secondary electrons or backscattered electrons, emanate from the surface of the wafer. Their start points correspond to those locations on the sample onto which the plurality of individual primary particle beams are focused in each case. The amount and the energy of the interaction products depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises several detection regions, each of which may comprise several detection pixels, and the detector acquires an intensity distribution for each of the secondary individual particle beams. An image field of 100 μm×100 μm, for example, is obtained in the process.

A known multi-beam electron microscope comprises a sequence of electrostatic and magnetic elements. At least some of the electrostatic and magnetic elements are adjustable in order to adapt the focus position and the stigmation of the plurality of individual charged particle beams. Such a known multi-beam system with charged particles moreover comprises at least one cross-over plane of the primary or the secondary individual charged particle beams. Moreover, such a known system comprises detection systems in order to facilitate the adjustment. Such a known multi-beam particle microscope comprises at least one beam deflector (“deflection scanner”) for collective scanning of a region of the sample surface via the plurality of individual primary particle beams in order to obtain an image field of the sample surface.

In the case of scanning electron microscopes for wafer inspection, it is usually desirable to keep the imaging conditions stable such that the imaging can be carried out with great reliability and high repeatability. The throughput generally depends on a plurality of parameters, for example the speed of the stage and of the realignment at new measurement sites, and the area measured per unit of capture time. The latter is determined, inter alia, by the dwell time on a pixel, the pixel size and the number of individual particle beams. Additionally, time-consuming image postprocessing may be involved from multi-beam electron microscope. For instance, the signal created from charged particles by the detection system of the multi-beam system are to be digitally corrected before the image field from a plurality of image subfields or partial images is put together (“stitching”).

Here, the raster positions of the individual particle beams on the sample surface can deviate from the ideal raster position in a plane arrangement. The resolution of the multi-beam electron microscope can be different for each of the individual particle beams and can depend on the individual position of the individual particle beam in the field of individual particle beams, and consequently can depend on the specific raster position of said individual particle beam.

Certain conventional systems of charged particle beam systems can be considered as being stretched to their limits with increasing demands on resolution and throughput.

One approach for improving precision and resolution lies in the use of a so-called autofocus. Here, while scanning the sample surface, the current focal position of the individual electron beams is ascertained continuously (“on-the-fly”) in view of the sample surface/object plane and an appropriate correction of the focal position is undertaken. For instance, the focus settings of the individual particle beams are adapted for each image field. For instance, this procedure is based on a model of the sample or the assumption that the sample properties do not change much from image field to image field such that prediction values for improved focusing can be ascertained by extrapolation or interpolation.

Nevertheless, known autofocus methods are often comparatively slow. This is at least partially because the focal position is optimized either by changing the working distance (WD) or by way of a different control of the objective lens. If there is different control of the objective lens or of other magnetic lenses for the purpose of varying the focal position, then this adjustment can be comparatively slow. It is known to use magnetic objective lenses and immersion lenses, for example, in which the magnetic field of a lens does not follow the lens excitation (current through the coil of a lens) in the dynamic case. A coil body or winding body made of a material with good thermal conductance has been used to dissipate the heating power of the coil. Since thermal and electrical conductivity accompany one another, the coil body acts as a short-circuited turn, on which a current is induced by a dynamic lens excitation. The induced current counteracts the dynamic change of the excitation. Thus, the dynamic change is compensated and not transferred to the magnetic lens field-shaping pole shoes at higher frequencies. Electrical compensation of the lens coil inductance for the purpose of controlling the desired time profile of the magnetic lens field via the lens current (dynamic closed-loop control) thus comes to nothing. Known attempts to reduce the lens coil inductance can fall short in the case of strong lenses which involve cooling.

To address the above-described issue, WO 2022/069073 A1 has disclosed a multiple particle beam system with a fast autofocus. To this end, at least one fast autofocus correction lens is used for setting the focus quickly. This lens can have different embodiments, for instance it can be embodied as a fast electrostatic lens or as an air-core coil. Air-core coils are inductive components without a soft-magnetic core and have relatively low inductances in comparison with coils with a soft-magnetic core. Air-core coils can also be used as fast autofocus correction lenses.

U.S. Pat. No. 5,708,274 discloses a particle-optical lens with a bent optical axis. This can lead to aberrations which can be corrected by way of coil pairs.

DE 100 44 199 A1 discloses a special magnetic lens arrangement with a correction magnetic field which can allow the particle-optical axis to be offset in parallel with the axis of symmetry of the arrangement.

DE 27 52 598 A discloses a fast electron-optical lens. Specifically, a special arrangement of a first magnetic lens within a second magnetic lens is proposed, wherein a shielding in the form of a ring-shaped body made of highly permeable high-frequency ferrite is provided between the magnetic lenses.

Known magnetic lenses with a soft-magnetic core or with pole shoes can have a higher inductance and in general are not considered to be quickly controllable or dynamically operable. The time-limiting elements of multiple particle beam systems thus continue to be the known magnetic lenses, which for example include magnetic field lenses, magnetic projection lenses and a magnetic objective lens.

In addition to a fast autofocus correction, there can be various other issues where systems with a higher throughput are desirable, for instance in the case of a dynamic readjustment of a multiple particle beam system, in the case of the recording of focus series, involved fast adaptations of a detection path on account of sample charging, etc. A fast controllability, i.e. a dynamic controllability, of (strong) magnetic lenses would therefore be desirable overall.

### SUMMARY

The present disclosure seeks to provide a multiple particle beam system that operates with charged particles and an associated method for operating same with a high throughput, which can help enables a relatively precise measurement of semiconductor features with an accuracy of below 1 nm, below 0.3 nm or even 0.1 nm.

The disclosure seeks to provide a multiple particle beam system which can help enables relatively precise and high-resolution image recording with relatively high throughput.

The present disclosure seeks to provide an alternative multiple particle beam system which allows a relatively fast dynamic control of the system. For example, even strong magnetic lenses which involve active cooling should be rendered quickly controllable such that it is possible to avoid additional weak lenses without active cooling.

The disclosure can be considered as breaking with certain dogma of particle optics that magnetic lenses with high inductances per se are not quickly switchable or are only dynamically controllable with a low bandwidth of a few hertz. Thus, workarounds such as a switch to electrostatic lenses were not sought-after. Instead, there was a purposeful improvement of existing magnetic lenses.

Within the scope of the disclosure, the inventors examined strong magnetic lenses and their behaviour during dynamic control in great detail. It is known that so-called iron losses can limit the bandwidth with which magnetic lenses can be controlled. In this case, these so-called iron losses generally relate to the iron core or, in the context of particle optics, the pole shoes of magnetic lenses. Magnetic lens bandwidth-limiting eddy currents may arise in these pole shoes in the case of a dynamic control. This issue is known within the scope of constructing transformers, and there are solution approaches to this end. However, simply implementing these does not lead to a decisive improvement in the control behaviour of strong magnetic lenses in particle optics.

Comparatively large amounts of heat are created, and are to be dissipated, in the case of strong magnetic lenses. Thus, the utilized coil body or winding body normally comprises a cooling line arrangement, and the winding body itself therefore desirably exhibits good thermal conductivity. However, a good thermal conductivity typically correlates with a high electrical conductivity. Thus, electrical eddy currents can arise during the dynamic control of magnetic lenses. Thus, when designing the winding body according to certain known approaches, a compromise can be considered as being made between the desired thermal conductivity on the one hand and the unwanted high electrical conductivity on the other hand. In particle optics, copper is often used as the material for the winding body of a magnetic lens. Additionally, accompanying measures may be taken, for instance the use of additional, small dynamic lenses with small winding bodies or entirely without winding bodies and the use of relatively suitable materials for lens parts and beam tubes, etc.

However, the disclosure provides a different approach to render also a strong magnetic lens, i.e. a magnetic lens involve active cooling, dynamically controllable over a relatively broad range. The disclosure proposes the separation of the winding body substantially parallel to the thermal flow and orthogonal to the electrical eddy currents created. This can reduce the arising eddy currents on the one hand but nevertheless can allow maximal cooling or heat dissipation on the other hand.

In a first aspect, the disclosure relates to a multi-beam particle beam system, for example a multi-beam particle microscope, comprising the following: a magnetic lens through which a plurality of individual charged particle beams pass; and a controller configured to control the magnetic lens, wherein the magnetic lens comprises a coil, a winding body and a pole shoe, wherein the coil is arranged around the winding body and wherein the winding body is designed as a hollow body through which the plurality of individual particle beams pass, wherein the coil, together with the winding body, is arranged within the pole shoe, wherein the pole shoe has an opening through which a magnetic field created by the magnetic lens emerges from the pole shoe and interacts with the plurality of individual particle beams in order to obtain a lens effect, wherein the winding body is electrically conductive and wherein the winding body has an interruption, by which the electrical conductivity of the winding body is interrupted in the circumferential direction around the particle-optical axis such that a creation of electrical eddy currents in the winding body around the particle-optical axis is reduced when the magnetic lens is controlled dynamically.

For instance, the individual charged particle beams can be electron beams, positron beams, muon beams or ion beams, or other charged particle beams. These can be electron beams.

The winding body can have an interruption, by which the electrical conductivity of the winding body is interrupted in the circumferential direction around the particle-optical axis. In this case, the electrical conductivity of the winding body can be interrupted in full or in part in the circumferential direction around the particle-optical axis. In the case of a symmetric design of the multi-beam particle beam system, the circumferential direction around the particle-optical axis is typically also precisely the direction in which electrical eddy currents would otherwise be caused in the winding body.

According to an embodiment of the disclosure, the interruption of the winding body is in the form of a slot. For instance, it is possible to accordingly truncate the winding body in full or in part before the coil is wound.

Exactly one interruption is provided in the winding body according to an embodiment of the disclosure. However, it is also possible to provide for more than one interruption and, in the process, nevertheless not cut apart the winding body in such a way that it is subdivided, or falls apart, into two halves. For instance, a first slot can be introduced into the winding body from above, and a further slot can be introduced into the winding body from below. In this case, the two slot portions can be arranged opposite one another, or they may be displaced relative to one another in the circumferential direction. Further slot portions are also possible.

According to an embodiment of the disclosure, the interruption in the winding body is oriented from the inside to the outside, for example in the radial direction. In addition to that or in an alternative, the interruption is formed along, for example parallel to, the particle-optical axis. In this context, the radial direction is understood to mean the direction that starting from the particle-optical axis of the multi-beam particle beam system runs radially outwardly perpendicular to the particle-optical axis. An interruption runs along the particle-optical axis whenever it has a certain extent along the particle-optical axis. This extent should also be considered given if the precise profile of the interruption is not parallel but e.g. only at an angle to the particle-optical axis. However, a parallelism to the particle-optical axis can be desirable since—due to the system symmetries usually present—a heat transport is implemented parallel to the particle-optical axis within a winding body. Where possible, it can be desirable for this heat transport to not be restricted by the interruption.

According to an embodiment of the disclosure, the interruption is in the form of a slot, wherein the following for instance applies to a width b of the slot: 100 μm≤b≤1000 μm. The slot used for the interruption can be very narrow, which is why it may be relatively easily producible. However, the slot can also be narrower or wider.

According to an embodiment of the disclosure, an insulator and/or a high-resistance material is arranged in the interruption, for example in a slot or the slot. The gap in the winding body which has arisen due to the interruption can thus be filled tightly, especially completely, in this way. For instance, it is possible to arrange a film as an insulator in the interruption. For instance, the following materials can be arranged in the interruption: Plastics, for example thermoplastic high performance plastics, for instance PEEK (polyether ether ketone), PP (polypropylene), PA (polyamides), POM (polyoxymethylenes), PET (polyethylene terephthalate), PC (polycarbonates), PES (polysulfones) or PEI (polyether imide). Alternatively, it is possible to arrange a ceramic in the interruption, for instance aluminium oxide (Al₂O₃) or a silicate ceramic.

Arranging an insulator and/or a high-resistance material into the interruption can help prevent the interruption from being bridged by adjacent metal parts. This can reduce the eddy currents on the one hand but can allow maximal cooling or heat dissipation on the other hand since the insulation layer can be very thin. Likewise, insulators can be used to compensate for the losses in mechanical stability created by the interruption or by a slot.

According to an embodiment of the disclosure, the winding body also comprises a cooling line arrangement for cooling the winding body, wherein the interruption is arranged such that the cooling line arrangement is not truncated by the interruption. The region where the cooling line arrangement is placed within the winding body can form a heat sink, and the heat flux arising in the winding body can be oriented towards the heat sink.

According to an embodiment of the disclosure, the winding body comprises a plate-like front piece. The plurality of individual charged particle beams pass through this plate-like front piece. The plate-like front piece can have e.g. a central opening and can be a constituent part of the hollow body formed by the winding body overall. The cooling line arrangement comprises an inflow and an outflow for a coolant which are arranged at an outer edge of the plate-like front piece. The cooling line arrangement can be arranged within the plate-like front piece of the winding body, for example in meandering fashion and, overall, substantially encloses the particle-optical axis once between the inflow and the outflow. The interruption can be arranged between the inflow and the outflow of the cooling line arrangement, and the interruption can interrupt the plate-like front piece, for example in the radial direction. If the plate-like front piece is also interrupted in this way, then eddy currents cannot flow around the particle-optical axis of the system in this plate-like front piece either. The cooling line arrangement itself need not be foregone in the plate-like front piece. The loop-like arrangement, i.e. the meandering arrangement, can allow the plate-like front piece to be provided with the cooling line arrangement over the greatest possible area, and can allow the formation of an efficient heat sink, even if an interruption is introduced into said plate-like front piece.

According to an embodiment of the disclosure, the controller is configured to control the magnetic lens dynamically at a frequency ≥20 Hz, for example ≥50 Hz, ≥100 Hz or ≥1000 Hz, using a control current. In this case, the magnetic lens can be configured such that the following relation applies to an axial magnetic field B_{dyn} of the magnetic lens created by the dynamic control:

$${B}_{dyn} / {B}_{s t a t} \geq \frac{1}{\sqrt{2}}$$

where Bₛₜₐₜ denotes an axially created magnetic field of the magnetic lens in the case of an appropriate static control of the magnetic lens and where the drop in amplitude by the factor

$$\frac{1}{\sqrt{2}}$$

corresponds in electronics to the generally conventional definition of the cut-off frequency or 3 dB bandwidth. Thus, the losses in the axially created magnetic field on account of the dynamic control are relatively small over relatively wide ranges, which is why the aforementioned quotient is greater than or equal to

$$\frac{1}{\sqrt{2}}$$

over wide ranges, i.e. greater than approximately 70.7% over long stretches. To ascertain these parameters for the magnetic lens, the control was modified, or linearly increased against the lens current frequency, in the case of a control current with constant maximum amplitude. At the same time, the axial magnetic field of the magnetic lens was measured in the interior of the lens for the respective control frequency using a sufficiently fast field-sensitive 1-axis measurement probe. In this case, the measured axial magnetic field extends along the particle-optical axis Z, i.e. in the z-direction. To control the coil at a constant current over a wide frequency range, the coil inductance was electronically compensated, i.e. the control voltage was adapted accordingly.

According to an embodiment of the disclosure, the magnetic lens is controllable over a bandwidth BW, wherein the following relation applies to the bandwidth BW: 0 Hz≤BW≤1500 Hz.

The disclosure has made it possible to dynamically control the magnetic lens over this range without the dynamic magnetic field B_{dyn} dropping below the value of

$$\frac{1}{\sqrt{2}}$$

in comparison with the static magnetic field Bₛₜₐₜ. The bandwidth for the magnetic lens provided by the disclosure is thus relatively large and up to three orders of magnitude larger than in the case of magnetic lenses in multi-beam particle beam systems according to certain known systems. There, a bandwidth BW to date has only been approximately 2 to 4 Hz.

According to an embodiment of the disclosure, the multi-beam particle beam system moreover comprises a current source for providing the above-described control current for the magnetic lens, wherein the current source is bandwidth-optimized for the dynamic control of the magnetic lens. It was found that the current source is limiting for the bandwidth behaviour of the magnetic lens at higher frequencies on account of the increasing impedance. By way of an appropriate modification of the control parameters of the current source, the cut-off frequency can be shifted to higher cut-off frequencies. According to these measures, the power of the current source or the output voltage of the current source still is, in generally, limiting in relation to the attainable bandwidth; however, these measures already make it possible to reach the aforementioned region of 1500 Hz.

According to an embodiment of the disclosure, the interruption of the winding body is complete in the direction of the particle-optical axis, for example parallel to the particle-optical axis, of the multi-beam particle beam system, and/or the interruption of the winding body is complete from the inside to the outside, for example in the radial direction. This can help enable complete suppression of eddy currents around the particle-optical axis, and the magnetic lens can be dynamically controllable with a relatively large bandwidth.

According to an alternative embodiment of the disclosure, the interruption of the winding body is incomplete in the direction of the particle-optical axis, for example parallel to the particle-optical axis, of the multi-beam particle beam system, and/or the interruption of the winding body is incomplete from the inside to the outside, for example in the radial direction. This incomplete interruption may be desirable. A radical reduction in the eddy currents can allow the bandwidth of the magnetic lens to be set at more than 50 Hz, or else at very much more than 50 Hz. However, this can increase the susceptibility to interference induced in the cabling. Interferences induced in the cabling can be input-coupled into the plurality of individual particle beams. This might be the case in the frequency range around 50 Hz or 60 Hz, as these frequencies often occur in laboratory surroundings.

It might be desirable to optimize the bandwidth such that it is fast enough for desired dynamic performance but that, conversely, excessive bandwidths are capped in order to preclude interfering influences on the plurality of individual particle beams. According to an embodiment of the disclosure, a connecting piece of the winding body with a defined resistance for a bandwidth limitation during a dynamic control of the magnetic lens is provided adjacent to the interruption in the direction of the particle-optical axis. In other words, the interruption of the winding body is not complete in the direction of the particle-optical axis. The choice of a defined connecting piece, i.e. the choice of a connecting piece with defined dimensions in the Z-direction, i.e. in the direction of the particle-optical axis, can help ensure a defined resistance in combination with the specific resistance of the chosen material.

According to a further embodiment of the disclosure, the magnetic lens comprises a switchable bridging mechanism configured to short circuit the winding body around the particle-optical axis at least in sections in the case of a static control of the magnetic lens, wherein the controller is configured to control the bridging mechanism. According to this embodiment of the disclosure, the bandwidth can be limited during static operation, with a large bandwidth naturally not being required during static operation. Conversely, however, a dynamic control of the magnetic lens can also be implemented over a large frequency range without a short circuit in this embodiment variant.

According to an embodiment of the disclosure, the bridging mechanism comprises at least one connectable turn arranged around the particle-optical axis of the multi-beam particle beam system. In this case, the bridging mechanism can be enclosed by the coil of the magnetic lens, because eddy currents are only created in that case for dynamic lens control.

According to an embodiment of the disclosure, the coil comprises at least two windings arranged on the same winding body. For instance, the windings can be wound in succession and/or above one another around the winding body. The provision of a plurality of winding bodies can help allow the coil excitation and hence the lens excitation to be divided among a plurality of windings, each with a lower inductance. This can help reduce the power used for a dynamic control of each winding, and it is possible to prevent potentially dangerous high control voltages for the coil which would otherwise involve special safety precautions (low voltage directive EN61010).

According to an embodiment of the disclosure, the coil comprises a first winding with a first number of turns and a second winding with a second number of turns, wherein the first number of turns is greater than the second number of turns. Moreover, the controller is configured to control the first winding statically and the second winding dynamically.

Even if iron losses within the pole shoes of the magnetic lens were not a primary cause for the previously unattained dynamic control of the magnetic lens, it might nevertheless still be desirable to reduce iron losses in the pole shoes, even in the already described dynamically controllable magnetic lens. It generally holds true that the operation of magnetic cores can give rise to losses in the core, the so-called iron losses or core losses, on account of the changing polarity of the magnetic field. They are composed of hysteresis losses, also referred to as reversal losses, the eddy-current losses, the excess or additional losses and the aftereffect losses. In relation to magnetic lenses from the field of particle optics, eddy-current losses generally make up the majority of the iron losses. These eddy currents are induced in a magnetic core or the pole shoe under a time-varying magnetic field. The arising eddy currents can heat the pole shoe material and can lead to losses, even at relatively low frequencies (50 Hz, 60 Hz). As a countermeasure to eddy-current losses, the construction of transformers and electric motors has disclosed the practice of embodying magnetic cores not as solid parts but in laminated fashion (“sheeted”). In the process, magnetic sheet steel punched or cut into shape is coated with a heat-resistant and insulating lacquer and layered in blocks with an orientation parallel to the magnetic field lines or rolled to form rings. The magnetic flux is thus distributed among individual fluxes in the individual sheets which are separated from one another, and thus only smaller eddy currents can form in said sheets, the power loss of which overall is significantly lower than in a solid material. The sheets are usually thinner than 1 mm. The thinner the sheet, the lower the eddy-current losses or the higher the possible operating frequency.

However, it conversely holds true in the field of particle optics that the magnetic field providing the lens effect are to be shaped relatively precisely in the region of the opening of a pole shoe of magnetic lenses. Hence, a homogeneous pole shoe material can be in the vicinity of the opening of a pole shoe in order to ensure this precise shaping of the magnetic field.

According to an embodiment of the disclosure, the pole shoe of the magnetic lens comprises a first region, which comprises the pole shoe opening, and a second region spaced apart from the pole shoe opening. The first region of the pole shoe comprises (or consists of) a first material, and the second region of the pole shoe comprises (or consists of) a second material which is different from the first material. In this case, the term material relates firstly to the chemical composition of the material, but secondly also to the specific production or configuration of the material. It is possible to choose an optimal material for the first region and also choose a different optimal material for the pole shoe for the second region.

According to an embodiment of the disclosure, the pole shoe comprises (or consists of) a solid material in a first region which comprises the pole shoe opening, and the pole shoe does not consist of a solid material in a second region spaced apart from the pole shoe opening. Here, the term solid material is understood in the generally conventional sense from material sciences. With regards to the choice of material for the first region of the pole shoe, materials with firstly a small hysteresis and secondly a sufficient saturation field strength can be used. Moreover, it may be desirable for the magnetic behaviour of the material to be as homogeneous as reasonably possible. According to an embodiment variant, the pole shoe can comprise (or consist of) an iron-nickel alloy, for instance Permenorm®, in the first region, and the pole shoe can comprise (or consist of), for instance, a powder core, a ferrite core or laminated sheets in the second region.

According to an embodiment of the disclosure, the second region of the pole shoes is laminated, for example sheeted, in such a way that at least in sections the laminas, for example sheets, are oriented in a manner substantially parallel to the magnetic field lines which are formed in the pole shoes during the operation of the multi-beam particle beam system. The laminas, for example sheets, can be arranged in a manner dependent on the specific shape of a pole shoe. For instance, if the pole shoe is U-shaped, appropriately arranged laminas, for example sheets, will be provided for every side of the U. Examples of laminated metal cores include NiFe alloy sheets with different nickel proportions, traded for instance under the following trade names: Permenorm; Megaperm; Ortonol; Permax or else Mu-metal; Permalloy; Supermalloy; Cryoperm; Ultraperm or Vacoperm.

According to an embodiment of the disclosure, μᵣ>10,000 applies to the magnetic permeability μᵣ of a pole shoe material in the pole shoe. For instance, this is the case for Permenorm®. The pole shoe material can have a thickness d, and the controller of the multiple particle beam system is configured to dynamically control the magnetic lens with a control current at a frequency f with

$$f > {f}_{s} = \frac{1}{π {μ}_{0} {μ}_{r} κ {d}^{2}}$$

where μ₀ denotes the vacuum permeability, κ denotes the electrical conductivity and fₛ denotes the critical frequency at which the skin depth

$$δ = \sqrt{\frac{1}{π {μ}_{0} {μ}_{r} κ f}}$$

corresponds to the material thickness d. If the magnetic permeability μᵣ of the pole shoe material is extremely high, this leads to eddy currents flowing only on the surface in non-laminated or non-slotted pole shoe parts and only penetrating into the material up to the so-called skin depth

$$δ = \sqrt{\frac{1}{π {μ}_{0} {μ}_{r} κ f}}$$

(μ₀ vacuum permeability, κ conductivity, f frequency). The skin depth becomes very small for highly permeable material, rendering “sheeting” of the material superfluous, or even counterproductive on account of the increase in surface. The reduced effective conductor thickness δ already allows such a reduction in eddy current strength that no slots or lamination are involved for highly permeable material. This works above the critical frequency f_{S}, at which the skin depth corresponds to the material thickness d, i.e.

$$f > {f}_{s} = \frac{1}{π {μ}_{0} {μ}_{r} κ {d}^{2}} .$$

While this condition is usually met in this embodiment of the disclosure for extremely highly permeable material (Permenorm® 3 mm thick fₛ≈0.1 Hz), this condition is almost never met for non-magnetic metals (copper 3 mm thick fₛ≈500 Hz). Thus, this can give rise to the embodiment of the disclosure of slotting non-permeable metals and preventing bridging by way of insulations, and of designing highly permeable, electrically conductive materials (e.g., for the pole shoes) with the smallest possible surface.

In addition to the above-described embodiments of the disclosure, further measures may contribute to the bandwidth-optimization of multi-beam particle beam systems. For instance, this can also include the appropriate design of beam tubes, in which the plurality of individual particle beams are usually guided. It is known that the use of thin, moderately conductive beam tubes is desirable in this context. Details regarding beam tubes are described, for example, in the German patent application with the application number 10 2022 124 933.6, which was not yet laid-open at the time of this patent application and the disclosure of which is incorporated in full in the present patent application by reference.

As a further accompanying measure, the multiple particle beam system according to an embodiment of the disclosure may comprise a housing and a magnetic shielding unit arranged therein, the latter at least in sections substantially enclosing the particle-optical beam path of the multiple particle beam system. To this end, the magnetic shielding unit can have at least one access opening for an electrical and/or mechanical feedthrough into the interior of the magnetic shielding unit, wherein a short-circuit body whose material has good electrical conductance and is paramagnetic or diamagnetic is arranged around the access opening in a manner terminating the latter. In this way, dynamic magnetic fields penetrating into the shielding can be compensated for by eddy currents induced in the short-circuit body. This can be relevant because it might not possible to make do without the access openings. For instance, they can be indispensable for an access to stop drives, for electrical feed lines or for an access to the micro-optics or for the beam head of multiple particle beam systems. For instance a copper insert, for instance a copper ring, may serve as short-circuit body. For instance, the latter might also be annealed in order to increase the conductivity. The concept of a short-circuit body around an access opening in the magnetic shielding unit can also be used independently of the present disclosure, i.e. independently of the specifically designed magnetic lens with the interruption in the winding body.

According to an embodiment of the disclosure, the magnetic shielding unit has a cylindrical embodiment at least in sections and comprises an outer cylinder and an inner cylinder. In this context, the term “cylinder” should not be understood strictly geometrically. Certain deviations from the cylindrical shape are naturally possible. In this embodiment of the disclosure, the outer cylinder comprises (or consists of) demagnetized ferromagnetic material, and the inner cylinder comprises (or consists of) a material which has good electrical conductance and is paramagnetic or diamagnetic. In general, it is relatively easy to produce this embodiment variant of the disclosure. However, it is also possible that the inner cylinder comprises (or consists of) demagnetized ferromagnetic material, and that the outer cylinder consists of a material which has good electrical conductance and is paramagnetic or diamagnetic.

According to an embodiment of the disclosure, the outer cylinder consists of Mu-metal and/or the inner cylinder consists of copper.

According to an embodiment of the disclosure, the multi-beam particle beam system is a multi-beam particle microscope. In this context, the magnetic lens with the interruption in the winding body can be arranged in the primary path of the multi-beam particle microscope or in the secondary path of the multi-beam particle microscope.

In general, the magnetic lens with the interruption in the winding body can be e.g. a condenser lens, a field lens, an objective lens or a projection lens.

Moreover, it is possible to provide a further magnetic lens with an interruption in the winding body or several further magnetic lenses with an interruption in the winding body, as already described above in a number of embodiments, in the multiple particle beam system.

In view of the diverse options for arranging the magnetic lens with an interruption in the winding body, as described herein, in the particle-optical beam path, explicit reference is once again made to WO 2022/069073 A1, the disclosure of which is incorporated in full in the present patent application by reference. The magnetic lenses in the primary path and/or in the secondary path disclosed therein can be bandwidth-optimized, i.e. provided with the interruption according to the disclosure.

In an aspect, the disclosure relates to the use of a multi-beam particle beam system as described above in a plurality of embodiment variants, for example for a fast focus correction of individual particle beams. Once again, in the case of a multi-beam particle microscope, this fast focus correction can be carried out in the primary path, i.e. upon incidence on a sample, and/or in the secondary path, i.e. upon incidence on a detection unit.

In an aspect, the disclosure relates to the use of the multiple particle beam system as described above in a plurality of embodiment variants, for the recording of a focus series. A focal position can be modified relatively quickly when a focus series is recorded. For instance, this may be desirable for the ascertaining the current adjustment state of a multiple particle beam system.

In an aspect, the disclosure relates to the use of the multiple particle beam system as described above in a plurality of embodiment variants, for example for a dynamic readjustment of the multiple particle beam system. For instance, this may be desirable on account of sample charging, especially in the secondary path of a multiple particle beam system.

In an aspect, the disclosure relates to the use of the multiple particle beam system as described above in a plurality of embodiment variants, for example for a relatively fast switchover between various work points of the multiple particle beam system. For instance, a working distance can be modified relatively quickly in the process, such as using a relatively quick switch of a magnetic objective lens with a high inductance.

The above-described embodiments and aspects of the disclosure can be combined with one another in full or in part, provided that no technical contradictions arise as a result.

### BRIEF DESCRIPTION OF THE DRAWINGS

The disclosure can be understood even better with reference to the accompanying figures. In the figures:

FIG. 1: schematically shows a multiple particle beam system using the example of a multi-beam particle microscope;

FIG. 2: schematically shows the structure of a magnetic lens with a winding body and cooling line arrangement;

FIGS. 3A-3C: schematically show the creation of eddy currents and the reduction thereof;

FIGS. 4A-4B: schematically shows a winding body with an interruption and cooling line arrangement;

FIGS. 5A-5B: schematically shows a winding body with a cooling line arrangement and interruption in cross section and in a first section direction through the cross section;

FIG. 6: schematically shows a winding body with a cooling line arrangement and interruption in a first section direction through the cross section, wherein the cooling line arrangement has an even number of cooling turns;

FIGS. 7A-7B: schematically show the winding body with the cooling line arrangement and interruption from FIG. 6 in a second section direction and a second cross-sectional illustration;

FIG. 8: schematically shows a magnetic lens with a switchable bridging mechanism;

FIGS. 9A-9B: show measured curves for an excitation current in the magnetic lens and an associated axial magnetic field strength during a dynamic control of the magnetic lens;

FIG. 10: schematically shows measurement results of the bandwidth achieved for a fast magnetic lens;

FIGS. 11A-11C: schematically show a bandwidth optimization for a pole shoe of a magnetic lens via a pole shoe that is sheeted in sections;

FIGS. 12A-12B: schematically show a plurality of magnetic shielding units; and

FIGS. 13A-13B: schematically show a magnetic shielding unit with outer cylinder and inner cylinder.

### DETAILED DESCRIPTION

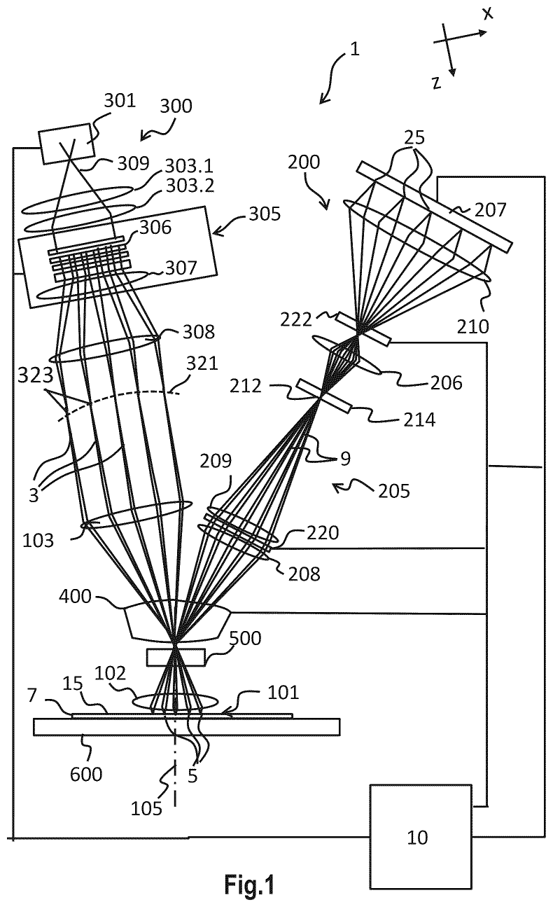

FIG. 1 schematically shows a multiple particle beam system using the example of a multi-beam particle microscope 1. The multi-beam particle microscope 1 comprises a beam generating apparatus 300 with a particle source 301, for instance an electron source. A divergent particle beam 309 is collimated by a sequence of condenser lenses 303.1 and 303.2 and incident on a multi-aperture arrangement 305. The multi-aperture arrangement 305 comprises several multi-aperture plates 306 and a field lens 308. A plurality of individual particle beams 3 or individual electron beams 3 are generated by the multi-aperture arrangement 305. Midpoints of apertures in the multi-aperture plate arrangement are arranged in a field which is imaged on a further field formed by beam spots 5 in the object plane 101. The pitch between the midpoints of apertures of a multi-aperture plate 306 can be for instance 5 μm, 100 μm and 200 μm. The diameters D of the apertures are smaller than the pitch of the midpoints of the apertures; examples of the diameters are 0.2 times, 0.4 times and 0.8 times the pitch between the midpoints of the apertures.

The multi-aperture arrangement 305 and the field lens 308 are configured to generate a plurality of focal points 323 of primary beams 3 in a raster arrangement on a surface 321. The surface 321 need not be a plane surface but rather can be a spherically curved surface in order to account for an image field curvature of the subsequent particle-optical system.

The multi-beam particle microscope 1 further comprises a system of electromagnetic lenses 103 and an objective lens 102, which image the beam foci 323 from the intermediate image surface 325 in the object plane 101 with reduced size. In between, the first individual particle beams 3 pass through the beam splitter 400 and a collective beam deflection system 500, by which the plurality of first individual particle beams 3 are deflected during operation and the image field is scanned. The first individual particle beams 3 incident in the object plane 101 for example form a substantially regular field, wherein the pitch between adjacent incidence locations 5 can be 1 μm, 10 μm or 40 μm, for example. For instance, the field formed by the incidence locations 5 can have a rectangular or hexagonal symmetry.

The object 7 to be examined can be of any desired type, for instance a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. For instance, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 μm, 100 μm and 200 μm.

The multi-beam particle microscope 1 further comprises a computer system or a control unit 10, which in turn can have a single-part or multi-part design and which is designed both to control the individual particle-optical components of the multi-beam particle microscope 1 and to evaluate and analyse the signals obtained by the multi-detector 207 or the detection unit.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is incorporated in full in the present application by reference.

The multi-beam particle microscope shown in FIG. 1 can be designed as a multiple particle beam system according to the disclosure and can comprise one or more magnetic lenses with an improved bandwidth with regards to a dynamic control. To this end, a (respective) winding body of the magnetic lens/of magnetic lenses can be designed with an interruption for reducing eddy currents.

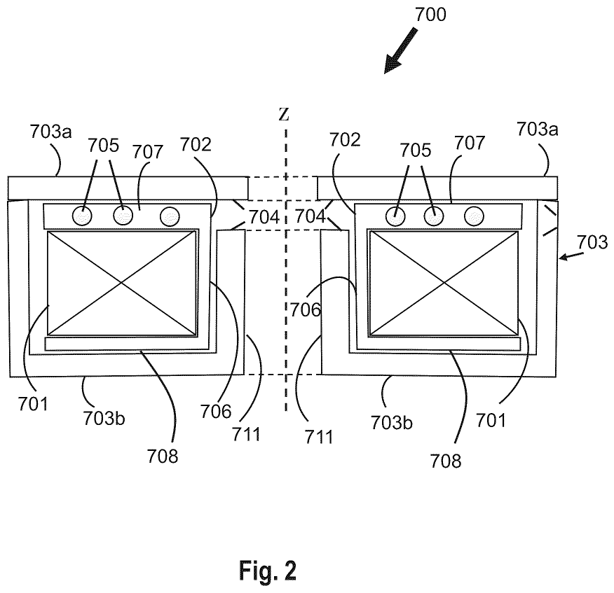

FIG. 2 schematically shows the structure of a magnetic lens 700. A section along the particle-optical axis Z is shown. The magnetic lens 700 comprises a coil 701 or winding 701, which may comprise a plurality of turns. In FIG. 2, the coil 701 is only depicted schematically as a component. The coil 701 is arranged around a winding body 702. In this case, the winding body 702 is in the form of a hollow body, i.e. it has a central opening such that the plurality of individual particle beams 3, 9 of the multiple particle beam system 1 can pass through the winding body 702. The coil 701, together with winding body 702, is arranged within a pole shoe 703. In the example shown, the pole shoe 703 is divided into an upper pole shoe 703a and a lower pole shoe 703b. The pole shoe 703 overall has an opening 704 which is situated between the upper pole shoe 703a and the lower pole shoe 703b and through which a magnetic field generated by the magnetic lens 700 emanates from the pole shoe 703 of the magnetic lens 700 and interacts with the plurality of individual particle beams 3 in order to obtain a lens effect.

In the example shown, the winding body 702 comprises a plate-like front piece 707, a middle piece 706 and an end piece 708. In the example shown, the winding body 702 has good electrical conductivity; for instance, it may comprise (or consist of) copper. The good electrical conductivity is also accompanied by good thermal conductivity. Hence, the winding body 702 is able to guide or dissipate arising heat if, like in the example shown, a cooling line arrangement 705 is integrated in the winding body 702. In the example shown, such a cooling line arrangement 705 is arranged in the plate-like front piece 707 of the winding body 702. In this case, FIG. 2 shows a section through three individual cooling lines. In an example, the magnetic lens 700 depicted in FIG. 2 substantially has a rotational symmetry about the axis or particle-optical axis Z.

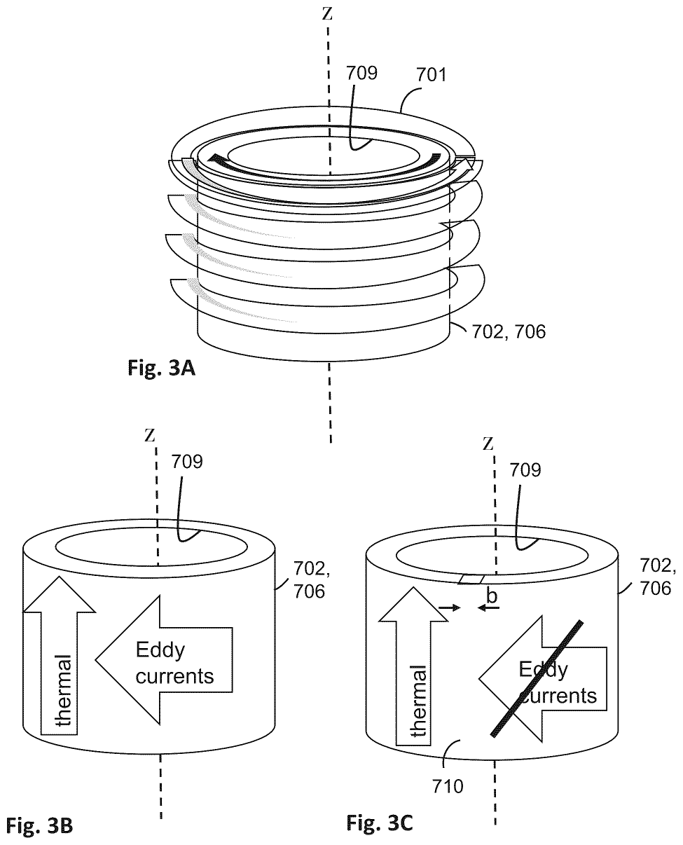

Now, eddy currents may arise in a magnetic lens 700 as depicted in FIG. 2 if the magnetic lens 700 is controlled dynamically, i.e. if the magnetic lens 700 is controlled quickly: FIG. 3A) shows sections of the middle piece of the winding body 702, which is surrounded by the coil 701 with a plurality of turns. On account of its ring structure or hollow body property, the winding body 702 corresponds to a coil with a single turn. Now, a change in the current in the winding 701 within the scope of a dynamic control of the magnetic lens 700 is also accompanied by a change in the magnetic field or magnetic flux within the coil 701 and hence also within the winding body 702, whereby an electrical eddy current is caused. In this case, the direction of the electrical eddy current is oriented in the opposite sense to the current direction in the coil 701 and thus attenuates the magnetic field generated in the coil 701 overall. The directions of the eddy current and current flow in the coil 701 are indicated by the arrows in FIG. 3A).

FIG. 3B) once again depicts the situation in the winding body 702 or in the associated middle piece 706 in its own right: Eddy currents around the axis Z arise in the winding body 702 or its middle piece 706 in the case of a dynamic control of the magnetic lens 700, and there is a heat flux or thermal flux along the Z-axis in the winding body 702 on account of the heat arising in the winding body 702 or on account of the heat sink provided by the cooling line arrangement 705. In FIG. 3B), this is depicted as an arrow from bottom to top by way of example.

FIG. 3C) now schematically illustrates a fundamental concept of the disclosure: The winding body 702 has an interruption 710, by which the electrical conductivity of the winding body 702 is interrupted in the circumferential direction around the particle-optical axis such that a creation of electrical eddy currents in the winding body 702 around the particle-optical axis Z is reduced when the magnetic lens 700 is controlled dynamically. In FIG. 3C), the reduction in the eddy currents is illustrated by the strikethrough arrow. However, the thermal conductivity in the winding body 702 is maintained at the same time.

In the schematic example illustrated, the interruption 710 extends along the particle-optical axis Z, even parallel to the particle-optical axis Z in this case. Additionally, the interruption 710 of the winding body 702 is oriented from the inside to the outside, even exactly in the radial direction in this case. Moreover, the interruption 710 is complete in the example shown, i.e. the winding body 702 is interrupted completely such that eddy currents around the particle-optical axis Z are completely suppressed in the winding body 702.

In the example shown, an insulator and/or high-resistance material is arranged in the interruption 710. For instance, the following materials can be arranged in the interruption 710: Plastics, for example thermoplastic high performance plastics, for instance PEEK (polyether ether ketone), PP (polypropylene), PA (polyamides), POM (polyoxymethylenes), PET (polyethylene terephthalate), PC (polycarbonates), PES (polysulfones) or PEI (polyether imide). Alternatively, it is possible to arrange a ceramic in the interruption 710, for instance aluminium oxide (Al₂O₃) or a silicate ceramic.

Moreover, the interruption 710 is designed as a slot in the example shown. This realization can be relatively simple. However, it is theoretically also possible to provide a curved interruption or a zigzag interruption, etc. In this context, it is sufficient to provide a narrow slot as interruption 710 in the winding body 702. By way of example, a width b of the slot can be between 100 μm and 1000 μm. However, the width b can also be less than 100 μm or greater than 1000 μm. In this case, the depth of the slot is e.g. identical to the radial extent of the winding body 702.

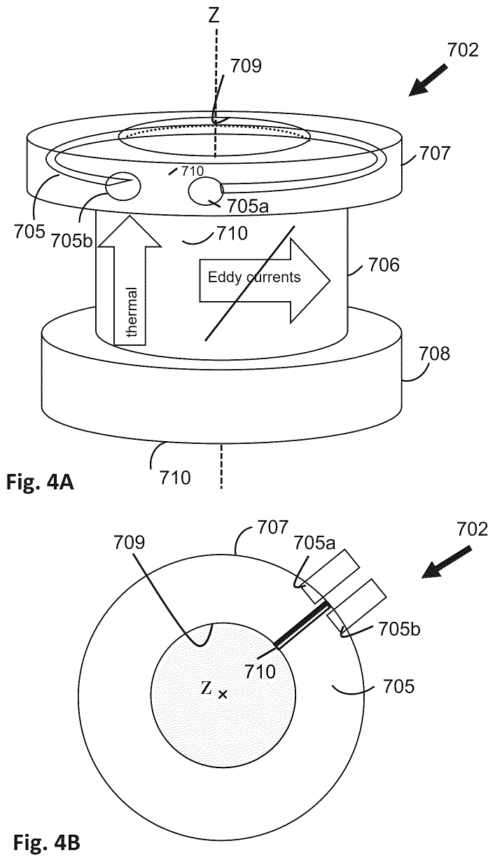

FIGS. 4A-4B schematically show a winding body 702 having a plate-like front piece 707, a middle piece 706 and an end piece 708 also with a plate-like design in the example shown. In the example shown in FIG. 4A), an interruption 710 is once again provided; it extends along the particle-optical axis Z and completely cuts open the winding body 702 in this direction. Moreover, the perspective view of FIG. 4A) schematically depicts a cooling line arrangement 705 in the plate-like front piece 707. Said cooling line arrangement comprises an inflow 705a and an outflow 705b which are opposite one another in a plane orthogonal to the particle-optical axis Z and separated from one another by the interruption 710. In the example shown, the cooling line arrangement 705 extends in ring-shaped fashion around the axis Z in the plate-like front piece 707. In this case, the interruption 710 is arranged such that the cooling line arrangement 705 is not truncated by the interruption 710. Thus, the interruption 710 is arranged between the inflow 705a and the outflow 705b in the cooling line arrangement 705 and interrupts the plate-like front piece 707 in the radial direction and simultaneously extends over the entire height (in the z-direction) of the plate-like front piece 707. FIG. 4B) shows a corresponding schematic plan view of the plate-like front piece 707.

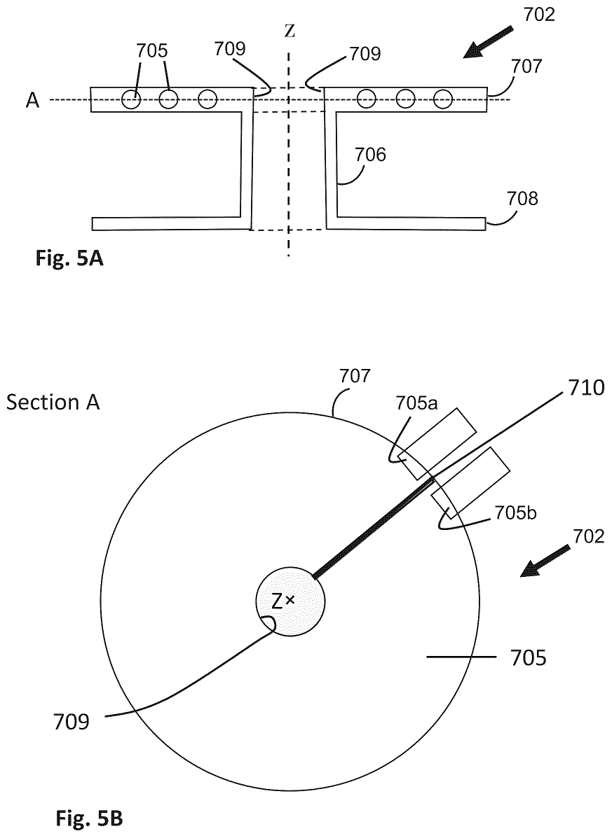

FIGS. 5A-5B schematically show a further exemplary embodiment of a winding body 702 with a cooling line arrangement 705. In this case, FIG. 5A) shows a cross section through the winding body 702, and FIG. 5B) shows a section along the line A as plotted in FIG. 5a). The section line A extends through three cooling line segments 705 on the left side of the Z-axis and through three further cooling line elements 705 on the right side of the Z-axis. The Z-axis itself extends centrally through the opening 709 in the winding body 702.

In general, the sectional representation along the line A corresponds to a plan view of the winding body 702 and hence to a plan view of the plate-like front piece 707. Once again, the cooling line arrangement 705 comprises an inflow 705a and an outflow 705b. The cooling line arrangement 705 is arranged within the plate-like front piece 707 of the winding body 702 in meandering fashion in the example shown and, overall, substantially encloses the particle-optical axis Z once between the inflow 705a and the outflow 705b. The meander-like arrangement of the cooling line arrangement 705 exploits the space available in the plate-like front piece 707 for the cooling, or in general the area of the plate-like front piece 707, better than a simple ring-shaped arrangement of a cooling line arrangement 705 as shown in FIG. 4A). It is also true in the example according to FIG. 5B) that the interruption 710 is arranged between the inflow 705a and the outflow 705b of the cooling line arrangement 705. The interruption 710 interrupts the plate-like front piece 707 in the radial direction. In this case, it extends through the entire front piece 707, i.e. it is complete.

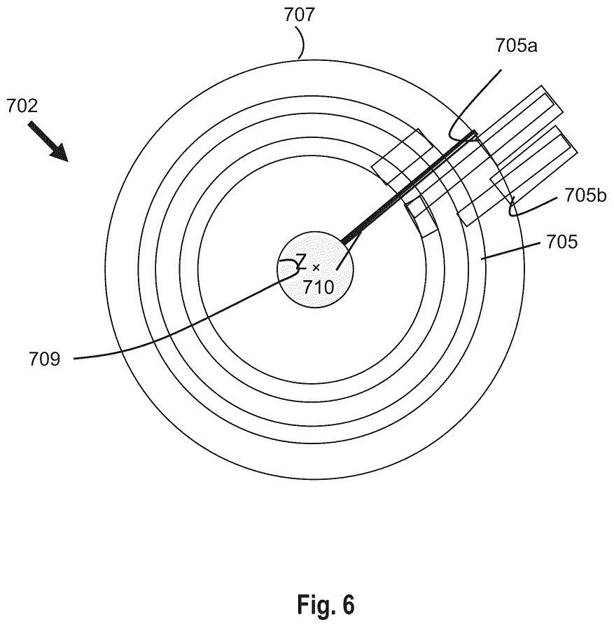

FIG. 6 schematically shows an alternative exemplary embodiment of a winding body 702 with a cooling line arrangement 705. The cooling line arrangement 705 is once again arranged within the plate-like front piece 707 of the winding body 702 in meandering fashion in the example shown and, overall, substantially encloses the particle-optical axis Z once between the inflow 705a and the outflow 705b. However, the number of cooling turns is even in this embodiment variant-unlike the embodiment variants shown in FIGS. 4A-4B (one cooling winding) and FIG. 6 (three cooling windings). The inflow 705a and the outflow 705b for the coolant can be situated on the same side of the interruption 710 in the case of an even number of cooling line turns of the cooling line arrangement 705.

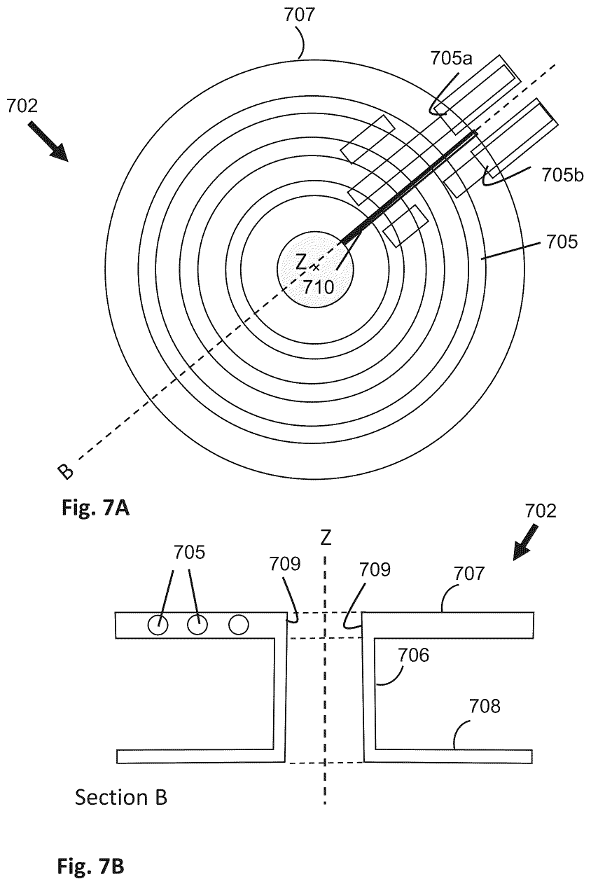

FIGS. 7A-7B schematically shows the winding body 702 with the cooling line arrangement 705 and the interruption 710 from FIGS. 5A-5B in a second section direction and in a second cross-sectional illustration. The section along the line B is now placed directly next to the interruption 710. Accordingly, the cooling line arrangement 705 can only be identified to the left of the particle-optical axis Z in the section B shown in FIG. 7B). On the right-hand side there is an edge region of the plate-like front piece 707 or this is directly adjacent to the interruption 710 itself. Otherwise, it once again holds true that the interruption is slot-like, and that an insulator and/or a high-resistance material can be arranged in the interruption.

In the examples described above, the interruption 710 of the winding body 702 was complete, to be precise both along the Z-axis and from the inside to the outside, for example radially. However, it is also possible to provide the interruption 710 of the winding body 702 incompletely in the direction of the particle-optical axis Z, for example parallel to the particle-optical axis Z, of the multiple particle beam system 1. In addition to that or in an alternative, it is also possible to provide the interruption 710 of the winding body 702 incompletely from the inside to the outside, for example in the radial direction. This incomplete interruption 710 may be desirable. A radical reduction in the eddy currents allows the bandwidth of the magnetic lens to be set in part at significantly more than 50 Hz. However, this also increases the susceptibility to interferences induced in the cabling, which are able to be input-coupled into the plurality of individual particle beams 3 as a result. This might be especially the case in the frequency range around 50 Hz or 60 Hz, as these frequencies frequently occur in laboratory surroundings. Thus, it might be desirable to optimize the bandwidth such that it is fast enough for desired dynamic properties but that, conversely, excessive bandwidths are actively capped in order to preclude interfering influences on the plurality of individual particle beams 3. Thus, according to an embodiment of the disclosure, a connecting piece of the winding body 702 with a defined resistance for a bandwidth limitation during a dynamic control of the magnetic lens 700 is provided adjacent to the interruption 710 in the direction of the particle-optical axis Z. As a result, the interruption 710 of the winding body 702 is not complete in the direction of the particle-optical axis Z. Thus, it is possible that eddy currents within the winding body 702 are able to flow around the Z-axis in the non-interrupted region. The choice of a defined connecting piece, i.e. the choice of a connecting piece with defined dimensions in the z-direction, ensures a defined resistance.

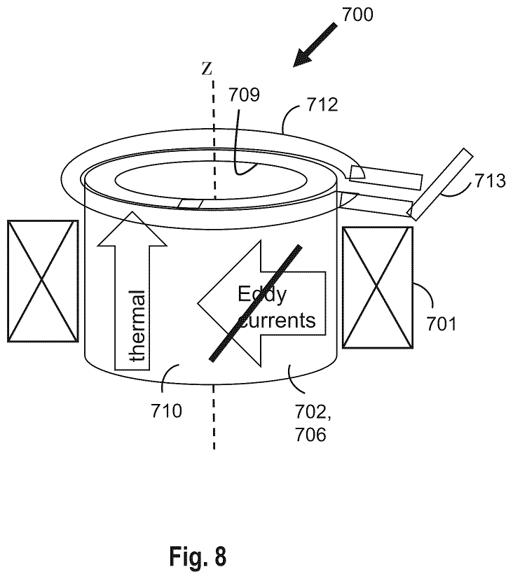

FIG. 8 schematically shows a magnetic lens 700, in which there can in fact be a change or switchover between a complete interruption 710 and an incomplete interruption 710: To this end, the magnetic lens 700 comprises a switchable bridging mechanism 712, 713 configured to short circuit the winding body 702 around the particle-optical axis Z at least in sections in the case of a static control of the magnetic lens 700. In this case, the controller 10 of the multiple particle beam system 1 is configured to control the bridging mechanism 712, 713. In the exemplary embodiment shown, the bridging mechanism comprises a connectable turn 712 arranged around the particle-optical axis of the multiple particle beam system 1. A short-circuit switch 713 which can be controlled via the controller 10 is provided for switching purposes. Other embodiment variants for a switchable bridging mechanism 712, 713 are also possible.

In addition to that or in an alternative, the coil 701 may comprise at least two windings arranged on the same winding body 702 (not depicted here). For instance, the windings can be wound in succession and/or above one another around the winding body 702. The provision of a plurality of winding bodies allows the coil excitation and hence the lens excitation to be divided among a plurality of windings, each with a lower inductance. This allows a reduction in the power used for a dynamic control of each winding, and it is possible to prevent potentially dangerous high control voltages for the coil which would otherwise involve special safety precautions (low voltage directive EN61010). According to an example, the coil 701 can comprise a first winding with a first number of turns and a second winding with a second number of turns, wherein the first number of turns is greater than the second number of turns. Moreover, the controller 10 can be configured to control the first winding of the coil 701 statically and the second winding of the coil 701 dynamically.

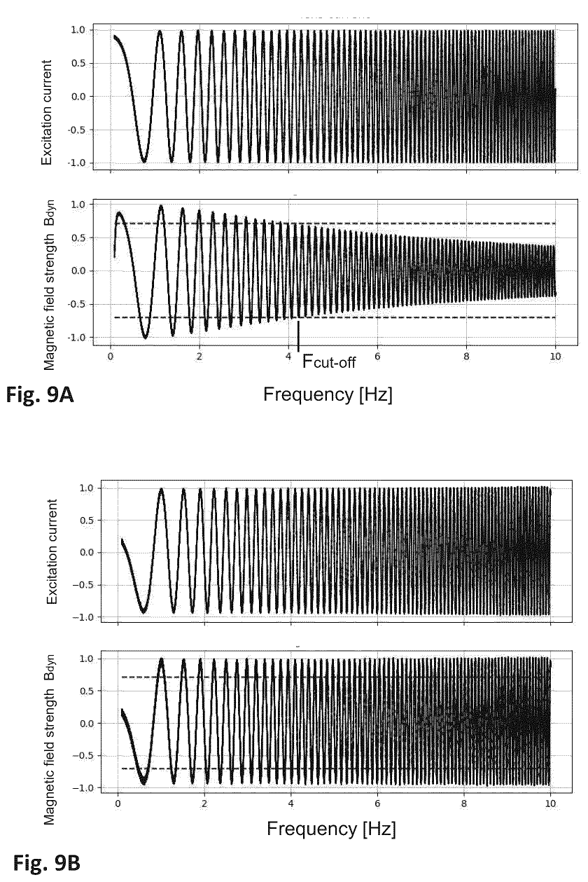

FIGS. 9A-9B illustrate the improved dynamic controllability of a multiple particle beam system 1 according to the disclosure or of the special magnetic lens 700 with an interruption 710 in the winding body 702 arranged therein: FIG. 9A) depicts measurement results for a magnetic lens 700 without an interruption 710 in the winding body 702. The top graph plots the normalized excitation current against the control frequency, the frequency given in Hz. In the process, the control current was increased over the frequency. At the same time, the magnetic field strength B_{dyn} achieved during the dynamic control of the magnetic lens 700 was measured in the interior of the magnetic lens 700. Specifically, the z-component of the magnetic field strength, i.e. the strength thereof along the particle-optical axis Z, was determined. The magnetic field strength B_{dyn} was plotted likewise in normalized fashion in the lower curve. It is evident here that there is only a minor drop below the maximum absolute value in the case of low frequency control up to control at a frequency of approximately 2 Hz. However, the drop in magnetic field strength B_{dyn} becomes ever stronger above approximately 2 Hz, until this drop falls below the value of

$$\frac{1}{\sqrt{2}}$$

at slightly above 4 Hz. The magnetic field strength B_{dyn} drops below the fraction

$$\frac{1}{\sqrt{2}}$$

of the maximum value (corresponding to the static control Bₛₜₐₜ) at approximately 4.2 Hz; this value forms the so-called cut-off frequency f_{cut-off}. The bandwidth BW thus ranges from 0 to approximately 4.2 Hz in the case of the unslotted magnetic lens 700 and hence is comparatively narrow.

By contrast, FIG. 9B) shows the increased bandwidth of the dynamic control of the magnetic lens 700 which was provided with an interruption 710 according to the disclosure: The magnetic field strength B_{dyn} tracks the excitation current over the entire range from 0 to 10 Hz, and the magnetic field strength B_{dyn} does not drop at all. This stability also continues at frequencies of more than 10 Hz; however, this is not shown further in FIGS. 9A-9B for reasons of presentability.

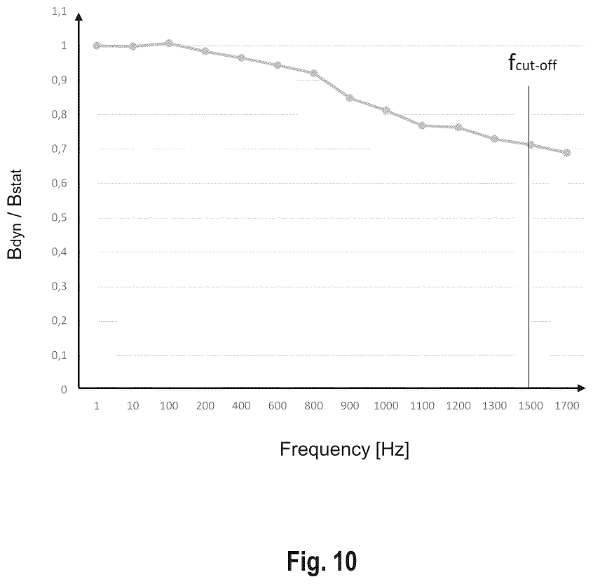

FIG. 10 schematically shows measurement results for the attained bandwidth BW for a fast magnetic lens 700 or a magnetic lens 700 with an interruption 710 for suppressing eddy currents in the winding body 702: The ratio of dynamic magnetic field strength B_{dyn} to static magnetic field strength Bₛₜₐₜ, each measured in the z-direction, is plotted against the frequency used to dynamically excite the magnetic lens 700. The ratio B_{dyn}/Bₛₜₐₜ is very large and comparatively stable over very wide frequency ranges. The cut-off frequency f_{cut-off} is only attained at a frequency of approximately 1500 Hz. In comparison with conventional magnetic lenses 700, it is thus possible to achieve a bandwidth increase by up to three orders of magnitude using the magnetic lens 700 which has been improved according to the disclosure. Thus, the bandwidth BW is up to 1500 Hz in the measurement example.

It is also possible to increase the bandwidth even further: This is because investigations by the inventors have yielded that the current source providing the excitation current for the magnetic lens 700 is limiting for the bandwidth behaviour of the magnetic lens 700 at frequencies even higher than 1500 Hz. By way of an appropriate modification of the current source, the cut-off frequency can be shifted to even higher cut-off frequencies. Additionally, the power of the current source or the output voltage of the current source can be modified or optimized further such that even higher bandwidths are attainable in general.

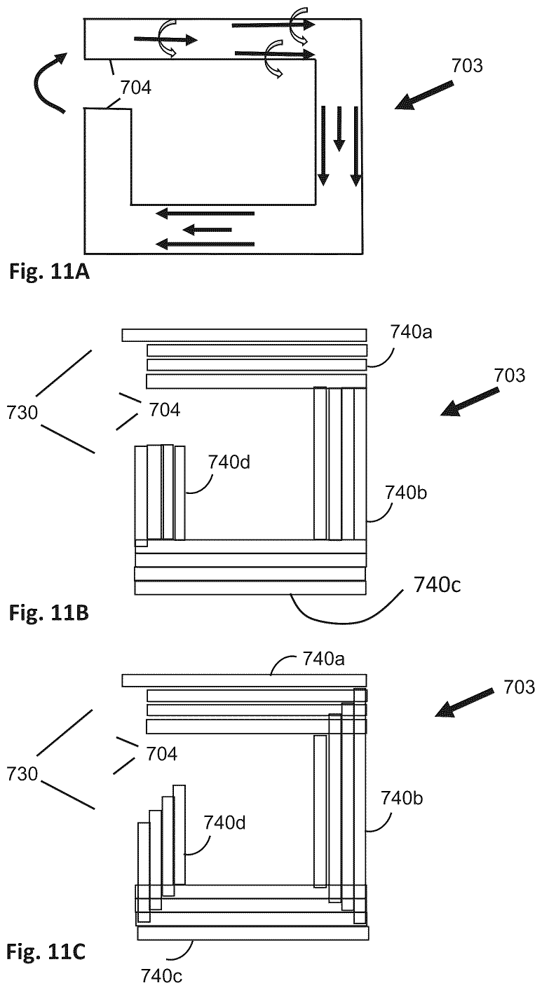

In addition to that or in an alternative, it is also possible to additionally minimize iron losses within a pole shoe 703 of the magnetic lens 700. FIGS. 11A-11C schematically show a bandwidth optimization for a pole shoe 703 of a magnetic lens 700 via a pole shoe 703 that is sheeted in sections. Specifically, FIG. 11A) shows the initial situation with a pole shoe 703 consisting of a solid material, for instance an iron-nickel alloy. Electrical eddy currents are formed around the magnetic field lines during a dynamic control of the magnetic lens 700. This attenuates field lines in the centre of the pole shoe 703. However, eddy currents generated in the edge region of the pole shoe 703 are interrupted, and so the dynamically excited magnetic flux is displaced out of the pole shoe 703 as a result. This displacement or the creation of eddy currents which attenuate the magnetic field centrally within the pole shoe 703 can now be prevented by sheeting. Two exemplary options in this respect are shown in FIGS. 11B) and 11C): The pole shoe 703 has a first region 730 and a second region 740 in both cases. The first region 730 comprises the pole shoe opening 704 and the second region 740 is spaced apart from the pole shoe opening 704. The materials from which the pole shoe is respectively constructed in the first region 730 and the second region 740 are different. The first region 730 which comprises the pole shoe opening 704 is constructed from a solid material. For instance, it consists of an iron-nickel alloy, for instance Permenorm®. Permenorm® provides a good compromise between a high saturation field strength and a high permeability, and a low coercivity. A solid material 730 can be in the region of the pole shoe opening 704 since the magnetic field generated via the magnetic lens 700 should emerge in a very defined manner from the pole shoe 703 in the region of this opening. This can be ensured well in the case of a homogeneous and, for example, solid material. By contrast, eliminating the eddy currents can be the focus in the region 740. The region 740 is therefore laminated or sheeted here.

In both the exemplary embodiment shown in FIG. 11B) and the exemplary embodiment shown in FIG. 11C), the laminas or sheets in this case are at least in sections oriented substantially parallel to the magnetic field lines within the pole shoe which are formed in the pole shoe 703 during the operation of the multiple particle beam system 1. The region 740 is divided into four subregions 740a, 740b, 740c, 740d in the example according to FIG. 11B). Each of these portions is cuboid. By contrast, the regions 740a, 740b, 740c and 740d are not cuboid in FIG. 11C); instead, they have at least in sections a stepped or pyramidal embodiment. The orientation of the sheets follows the magnetic field lines in the corners of the pole shoe 703 in a somewhat more exact manner in this embodiment variant. Naturally, other subdivisions of the laminated or sheeted region 740 into subregions are possible. In this respect, the illustrations in FIGS. 11A-11C show a concept of laminating or sheeting. Various NiFe alloy sheets with different nickel proportions can be used as material for the sheeting or the lamination in general. For instance, these are traded under the trade names of Permenorm, Megaperm, Ortonol, Permax or else Mu-metal, Permalloy, Supermalloy, Cryoperm, Ultraperm or Vacoperm.

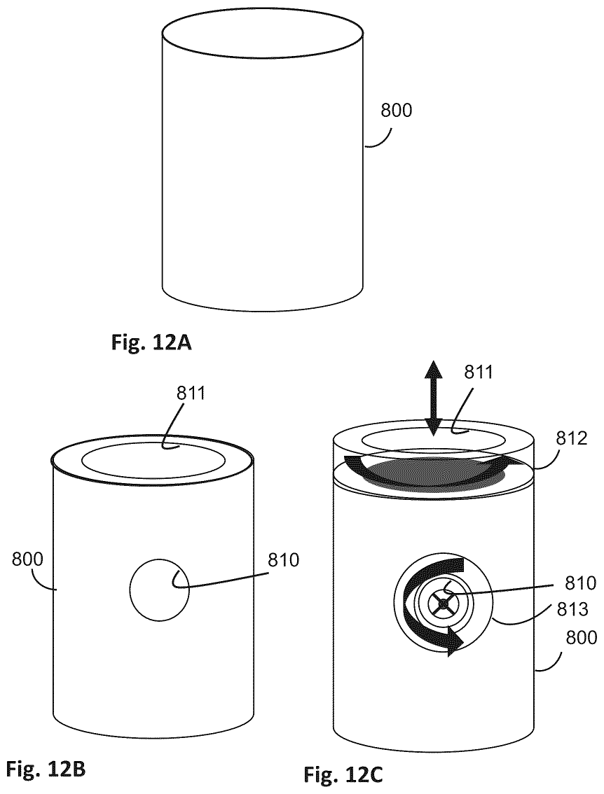

Further accompanying measures for increasing the bandwidth during the dynamic control of a magnetic lens 700 are possible. According to an example, a multiple particle beam system 1 may comprise a housing and a magnetic shielding unit 800 arranged therein, the latter at least in sections substantially enclosing the particle-optical beam path of the multiple particle beam system. Ideally, such a magnetic shielding unit 800 would be fully closed, for example a closed cylinder made of magnetic material such as Mu-metal, as depicted by way of example in FIG. 12A). However, the magnetic shielding 800 is not fully closed in practice; instead, it has mechanical and/or electrical feedthroughs in order to be able to operate the multiple particle beam system 1 within the shielding 800. For instance, access openings 810 and/or 811, depicted schematically in FIG. 12B), are used. For instance, a lateral opening 810 may be used for feed lines to micro-optics comprising a multi-beam particle generator 305 and/or for a displacement of stops in the particle-optical beam path, etc. An opening 811 from above may be used for a beam generator or beam head comprising the particle source 301, for example. The magnetic shielding is therefore “porous”. It is therefore possible that dynamic magnetic fields penetrate into the interior of the magnetic shielding 800 through the access openings 810, 811 and thus interfere with the particle-optical beam path. To prevent this, a short-circuit body 812, 813 whose material has good electrical conductance and is paramagnetic or diamagnetic can be arranged around an access opening 810, 811 in a manner terminating this access opening 810, 811. For instance, copper, gold and silver are diamagnetic metals, with copper often being desirable. In the example according to FIG. 12C), a cylindrical short-circuit body 812 is arranged in the region of the access opening 811, and a ring-shaped short-circuit body 813 is arranged around the lateral passage opening 810, with each short-circuit body consisting of copper for example. These short-circuit bodies 812, 813 each shield the dynamic magnetic field since eddy currents are generated in the short-circuit bodies 812, 813 in the case of alternating magnetic fields, and these eddy currents in turn attenuate the original alternating magnetic field. Thus, this way of completing the magnetic shielding 800 makes use of exactly the opposite effect to that used in the interruption 710 of eddy currents in the winding body 702 of the magnetic lens 700.

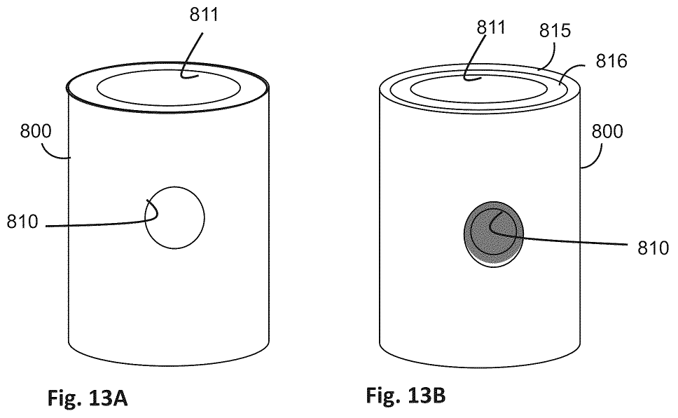

FIGS. 13A-13B schematically show a further example of a magnetic shielding unit 800 which, once again, has two access openings 810, 811 for an electrical and/or mechanical feedthrough into the interior of the magnetic shielding unit 800. In this case, too, a short-circuit body whose material has good electrical conductance and is paramagnetic or diamagnetic is arranged around the respective access opening 811, 810 in a manner terminating the access opening 810, 811. However, a geometrically different concept to this end is provided in the example shown, specifically the formation of the magnetic shielding unit 800 as outer cylinder 815 and inner cylinder 816 at least in sections. In this case, the outer cylinder consists of demagnetized ferromagnetic material, and the inner cylinder consists of a material which has good electrical conductance and is paramagnetic or diamagnetic. For instance, the outer cylinder 815 may comprise (or consist of) Mu-metal and/or the inner cylinder 816 may comprise (or consist of) copper. This embodiment variant for improved magnetic shielding can be produced relatively easily from a manufacturing point of view. However, it is alternatively also possible to make the inner cylinder from demagnetized ferromagnetic material and make the outer cylinder from a material which has good electrical conductance and is paramagnetic or diamagnetic.

Moreover, it is naturally possible to embody the disclosure about an improved magnetic shielding quite generally for multiple particle beam systems and not only in the context of the improved multiple particle beam system or the fast magnetic lens 700 with an interruption 710 in the winding body 702.

A multiple particle beam system 1 is disclosed, for example a multi-beam particle microscope 1, comprising the following: a magnetic lens 700 through which a plurality of individual charged particle beams 3, 9 pass; and a controller 10 configured to control, for example dynamically control, the magnetic lens 700. The magnetic lens 700 comprises a coil 701, a winding body 702, especially with a cooling line arrangement 705, and a pole shoe 703. The coil 701 is arranged around the winding body 702 and the winding body 702 is designed as a hollow body through which the plurality of individual particle beams 3, 9 pass. The coil 701, together with the winding body 702, is arranged within the pole shoe 703. The pole shoe 703 has an opening 704 through which a magnetic field created by the magnetic lens 700 emerges from the pole shoe 703 and interacts with the plurality of individual particle beams 3, 9 in order to obtain a lens effect. The winding body 702 is electrically conductive and has an interruption 710, by which the electrical conductivity of the winding body 702 is interrupted in the circumferential direction around the particle-optical axis. A creation of electrical eddy currents in the winding body 702 around the particle-optical axis Z is reduced when the magnetic lens 700 is controlled dynamically. As a result, the magnetic lens 700 of the multiple particle beam system 1 can be controlled dynamically with a large bandwidth BW up to 1500 Hz.

### LIST OF REFERENCE SIGNS

1 Multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
101 Object plane
102 Objective lens
103 Field lens
105 Axis
200 Detector system
205 Projection lens system
206 Projection lens
207 Multi-particle detector
208 Projection lens
209 Projection lens
210 Projection lens
212 Cross-over
214 Aperture filter, contrast stop
220 Multi-aperture corrector, individual deflector array
222 Collective anti-deflection system
300 Beam generating apparatus
301 Particle source
303 Collimation lens system
305 Multi-aperture arrangement, multi-beam particle generator
306 Micro-optics with multi-aperture plates
307 Field lens
308 Field lens
309 Particle beam
321 Intermediate image plane
323 Beam foci
400 Beam splitter, magnet arrangement
500 Scan deflector
503 Voltage source
600 Displacement stage or positioning device
700 Magnetic lens
701 Coil
702 Winding body
703 Pole shoe
704 Opening of the pole shoe for the magnetic field
705 Cooling line arrangement
705a Inflow
705b Outflow
706 Middle piece
707 Plate-like front piece
708 End piece
709 Opening of the winding body
710 Interruption
711 Passage opening in the pole shoe for particle beam(s)
712 Connectable turn
713 Short-circuit switch
730 First region of the pole shoe
740 Second region of the pole shoe
800 Magnetic shielding unit
810 Access opening
811 Access opening
812 Short-circuit body
813 Short-circuit body
815 Outer cylinder
816 Inner cylinder

1. A multiple particle beam system configured to generate a plurality of individual charged particle beams, the multiple particle beam system comprising:
a magnetic lens configured to have the plurality of individual charged particle beams pass therethrough; and
a controller configured to control the magnetic lens,
wherein:
the magnetic lens comprises a coil, a winding body and a pole shoe;
the coil is around the winding body;
the winding body comprises a hollow body configured to have the plurality of individual particle beams pass therethrough;
the coil and the winding body are within the pole shoe; and
the pole shoe comprises an opening configured to have a magnetic field created by the magnetic lens emerge therefrom;
the pole shoe is configured to interact with the plurality of individual particle beams to obtain a lens effect;
the winding body is electrically conductive;
the winding body comprises an interruption configured to interrupt the electrical conductivity of the winding body in a circumferential direction around a particle-optical axis of the multiple particle beam system to reduce electrical eddy current in the winding body around the particle-optical axis when the magnetic lens is controlled dynamically.

2. The multiple particle beam system of claim 1, wherein the interruption in the winding body is oriented from inside to outside, and/or wherein the interruption extends along the particle-optical axis.

3. The multiple particle beam system of claim 1, wherein the interruption comprises a slot.

4. The multiple particle beam system of claim 1, wherein the slot has a width that is at least 100 micrometers and at most 1000 micrometers.

5. The multiple particle beam system of claim 1, further comprise an insulator and/or a high-resistance material in the interruption.

6. The multiple particle beam system of claim 1, wherein the winding body comprises a cooling line arrangement that is not truncated by the interruption.

7. (canceled)

8. The multiple particle beam system of claim 1, wherein:
the controller is configured to control the magnetic lens dynamically at a frequency at least 20 Hertz via a control current;
the magnetic lens is configured so that the following relation applies to an axial magnetic field B_{dyn} of the magnetic lens created by the dynamic control:
$${B}_{dyn} / {B}_{s t a t} \geq \frac{1}{√ 2} ,$$
where Bₛₜₐₜ denotes an axially created magnetic field of the magnetic lens in the case of an appropriate static control of the magnetic lens.

9. (canceled)

10. The multiple particle beam system of claim 1, wherein the magnetic lens is dynamically controllable over a bandwidth of at most 1500 Hertz.

11. The multiple particle beam system of claim 1, wherein the interruption of the winding body is complete in the direction of the particle-optical axis, and/or wherein the interruption of the winding body is complete from inside to outside.

12. The multiple particle beam system of claim 1, wherein the interruption of the winding body is incomplete in the direction of the particle-optical axis, and/or wherein the interruption of the winding body is incomplete from inside to outside.

13. (canceled)

14. The multiple particle beam system of claim 1, wherein the magnetic lens comprises a switchable bridging mechanism configured to short circuit the winding body around the particle-optical axis in the case of a static control of the magnetic lens, and the controller is configured to control the bridging mechanism.

15. (canceled)

16. (canceled)

17. (canceled)

18. The multiple particle beam system of claim 1, wherein the pole shoe comprises a first material in a first region which comprises the pole shoe opening, the pole shoe comprises a second material in a second region spaced apart from the pole shoe opening, and the first material is different from the second material.

19. The multiple particle beam system of claim 1, wherein the pole shoe comprises a solid material in a first region which comprises the pole shoe opening, and the pole shoe does not comprise a solid material in a second region spaced apart from the pole shoe opening.

20. (canceled)

21. The multiple particle beam system of claim 1, wherein the pole shoe comprises a material having a magnetic permeability of greater than 10,000.

22. The multiple particle beam system of claim 21, wherein:
the material has a thickness d;
the controller is configured to dynamically control the magnetic lens with a control current at a frequency f;
$$f > {f}_{s} = \frac{1}{π {μ}_{0} {μ}_{r} κ {d}^{2}} ;$$
μ₀ denotes the vacuum permeability;
κ denotes the electrical conductivity; and
fₛ denotes the critical frequency at which the skin depth
$$δ = \sqrt{\frac{1}{π {μ}_{0} {μ}_{r} κ f}}$$
corresponds to d.

23. The multiple particle beam system of claim 1, further comprising a housing and a magnetic shielding unit arranged therein, wherein:
at least in sections, the magnetic shielding unit substantially encloses the particle-optical beam path;
the magnetic shielding unit comprises an access opening for an electrical and/or mechanical feedthrough into an interior of the magnetic shielding unit; and
a short-circuit body whose material has good electrical conductance and is paramagnetic or diamagnetic is arranged around the access opening in a manner terminating the latter.

24. (canceled)

25. (canceled)

26. The multiple particle beam system of claim 1, wherein the multiple particle beam system comprises a multi-beam particle microscope.

27. The multiple particle beam system of claim 1, wherein the magnetic lens comprises a condenser lens, a field lens, an objective lens or a projection lens.

28. The multiple particle beam system of claim 1, comprising a second magnetic lens, wherein:
the second magnetic lens comprises a second coil, a second winding body and a second pole shoe;
the second coil is around the second winding body;
the second winding body comprises a second hollow body configured to have the plurality of individual particle beams pass therethrough;
the second coil and the second winding body are within the pole shoe;
the second pole shoe comprises an opening to have a magnetic field created by the further magnetic lens emerge therefrom from the second pole shoe to interact with the plurality of individual particle beams to obtain a lens effect;
the second winding body is electrically conductive; and
the second winding body has an interruption, by which the electrical conductivity of the winding body is interrupted in the circumferential direction around the particle-optical axis to reduce electrical eddy currents in the second winding body around the particle-optical axis when the second magnetic lens is controlled dynamically.

29. A method, comprising:
using the multiple particle beam system of claim 1 to:
fast focus correct individual particle beams;
record a focus series;
dynamically readjust the multiple particle beam system; and/or
fast switchover between various work points of the multiple particle beam system.
